(19) United States
(12) Patent Application Publication
(10) Pub. No.: US 2025/0370357 A1
(43) Pub. Date: Dec. 4, 2025

(54) OPTICAL ASSEMBLY, OPTICAL SYSTEM AND PROJECTION EXPOSURE APPARATUS

(71) Applicant: Carl Zeiss SMT GmbH, Oberkochen (DE)

(72) Inventor: Roman ORLIK, Koenigsbronn-Zang (DE)

(21) Appl. No.: 19/304,494

(22) Filed: Aug. 19, 2025

Related U.S. Application Data
(63) Continuation of application No. PCT/EP2024/054384, filed on Feb. 21, 2024.

(30) Foreign Application Priority Data
Mar. 1, 2023 (DE) 10 2023 201 859.4

(51) Int. Cl. G03F 7/00; F16B 7/04; G02B 7/182

(52) U.S. Cl. CPC G03F 7/70825; F16B 7/0406; G02B 7/182; G03F 7/70233; G03F 7/70258

(57) ABSTRACT

An optical assembly for a projection exposure apparatus comprises an optical element, a support structure carrying the optical element, and a plurality of decoupling devices between the optical element and the support structure to mechanically decouple the optical element from the support structure. Each decoupling device comprises a first decoupling element and a second decoupling element connected to the first coupling element. The first decoupling element is connected to the optical element, and the second decoupling element is connected to the support structure.

### CROSS-REFERENCE TO RELATED APPLICATIONS

The present application is a continuation of, and claims benefit under 35 USC 120 to, international application No. PCT/EP2024/054384, filed Feb. 21, 2024, which claims benefit under 35 USC 119 of German Application No. 10 2023 201 859.4, filed Mar. 1, 2023. The entire disclosure of each of these applications is incorporated by reference herein.

### FIELD

The present disclosure relates to an optical assembly, to an optical system having such an optical assembly and to a projection exposure apparatus having such an optical assembly and/or such an optical system.

### BACKGROUND

Microlithography is used for producing microstructured components, for example integrated circuits. The microlithography process is carried out using a lithography apparatus, which has an illumination system and a projection system. The image of a mask (reticle) illuminated via the illumination system is projected via the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, EUV lithography apparatuses that use light at a wavelength ranging from 0.1 nm to 30 nm, such as 13.5 nm, are currently under development. In the case of such EUV lithography apparatuses, because of the high absorption of light at this wavelength by most materials, reflective optical units, which is to say mirrors, are typically used instead of—as previously—refractive optical units, which is to say lens elements.

Mirror sockets can be used to couple such mirrors to actuators. The actuators can be used to help align such mirrors. These mirror sockets may be adhesively bonded into the respective mirror on the back side. However, this is not mandatory. It is likewise possible to adhesively bond the mirror sockets to the mirror on the front side. An adhesive used to this end may shrink or expand, for example due to temperature or ageing. To address the introduction into the mirror of parasitic forces arising from a shrinkage or an expansion of the adhesive, cutouts or decoupling cuts may be provided on the optical element in the region of the mirror sockets. However, these generally involve additional installation space.

### SUMMARY

The present disclosure seeks to provide an improved optical assembly.

The disclosure proposes an optical assembly for a projection exposure apparatus. The optical assembly comprises an optical element, a support structure, which carries the optical element, and a plurality of decoupling devices which are arranged between the optical element and the support structure in order to mechanically decouple the optical element from the support structure, with each decoupling device comprising a first decoupling element and a second decoupling element connected to the first coupling element, the first decoupling element being connected to the optical element and the second decoupling element being connected to the support structure.

As a result of the decoupling devices being arranged between the optical element and the support structure, it is possible to significantly reduce an installation space used for the optical assembly.

The optical assembly can be a mirror or a mirror module or may be referred to as such. The optical element can be a mirror, such as an EUV mirror or a DUV mirror. However, the optical element can also be a lens element. The optical element can have an optically effective surface, such as a mirror surface. The optically effective surface is configured to reflect illumination radiation, for example EUV radiation or DUV radiation. The optically effective surface can be realized by a coating. The optically effective surface can face away from the support structure. The optical element comprises a back side facing away from the optically effective surface. The back side faces the support structure.

The support structure may be plate-shaped or block-shaped. In the present case, the support structure “carrying” the optical element means that, in particular, the support structure is able to absorb a weight of the optical element. The optical element is operatively connected to the support structure with the aid of the decoupling devices, with the decoupling devices however ensuring that the optical element is mechanically decoupled from the support structure. In particular, this means that the decoupling devices are connected both to the optical element and to the support structure. Hence, with the aid of the decoupling devices, the optical element is connected indirectly to the support structure.

In the present case, “mechanical decoupling” should be understood to mean that, in particular, forces from the support structure to the optical element, or vice versa, cannot be transmitted or at least can only be transmitted in part. Hence, the decoupling devices prevent, in particular, the transmission of unwanted forces from the support structure to the optical element. This can avoid unwanted deformations of the optical element or optically effective surface. In particular, the decoupling devices prevent the transmission of parasitic forces from the support structure to the optical element. In the present case, “parasitic forces” should be understood to mean, for example, forces that emerge from a differential heat-related expansion or shrinkage of components of the optical assembly.

There can be any desired number of decoupling devices. For example, at least three decoupling devices may be provided. However, four, five or more than five such decoupling devices may also be provided. In the present case, the decoupling devices being arranged “between” the optical element and the support structure means that, in particular, the decoupling devices are placed between the back side of the optical element and a front side of the support structure. Hence, the decoupling devices are arranged within the optical assembly in particular. Alternatively, however, the decoupling devices may also be arranged on the support structure to the side or back.

According to an embodiment, the decoupling devices are arranged within the optical element or on the optical element, at least in sections.

The optical element can comprise a multiplicity of recesses on its back side, with each recess being able to be assigned a decoupling device. For example, exactly one decoupling device may be arranged or accommodated in each recess. Each recess has a base connected to the respective decoupling device. The decoupling devices may project out of these recesses in the direction of the support structure. For example, this means that the decoupling devices, at least in sections, may also be arranged outside of the optical element.

According to an embodiment, the decoupling devices are configured to mechanically decouple the optical element both axially and laterally from the support structure.

Each coupling device can be assigned an axis of symmetry or centre axis, in relation to which the decoupling device has a substantially rotationally symmetric structure. In this context, “substantially” means that at least parts of the decoupling device may be constructed rotationally symmetrically with respect to the centre axis. In the present case, “axially” should be understood as meaning along the aforementioned centre axis. Accordingly, “laterally” means perpendicular to the centre axis or along a radial direction of the respective decoupling device. The radial direction is oriented perpendicularly to the centre axis and away from the latter.

According to an embodiment, the support structure has a greater stiffness than the optical element.

In this case, the “stiffness” should be understood to mean, in particular, the resistance of a body, the support structure or the optical element in the present case, to an elastic deformation applied by an external load. The stiffness provides the correlation between the load on the body and its deformation. The stiffness is determined by the substance of the body and its geometry. For example, in the case of two geometrically identical bodies, the body whose material or substance used to manufacture the respective body has the higher Young's modulus has the greater stiffness. Hence, the different stiffnesses of the optical element and support structure can be obtained by different geometries and/or by the use of different materials or substances.

According to an embodiment, the support structure is manufactured from a substance which has a higher Young's modulus than a substance used to manufacture the optical element.

The support structure can be manufactured from a more cost-effective substance than the optical element. As a result, the optical assembly can be produced cost effectively. For example, the optical element can be manufactured from Ultra Low Expansion Glass (ULE). However, other glasses, glass ceramics, ceramics or metallic substances can be used for the optical element. For example, the support structure may be manufactured from a metallic substance. For example, an iron-nickel alloy, in particular Invar, can be used for the support structure. However, non-metallic substances can also be used for the support structure. For example, the support structure may also be manufactured from silicon carbide (SiSiC).

Each decoupling device comprises a first decoupling element and a second decoupling element connected to the first decoupling element, with the first decoupling element being connected to the optical element and the second decoupling element being connected to the support structure.

The first decoupling element and the second decoupling element can each be constructed rotationally symmetrically with respect to the centre axis of the respective decoupling device. The first decoupling element can be constructed in ring-shaped fashion, at least in sections. However, the first decoupling element may also be triangular. The second decoupling element may be bolt-shaped or rod-shaped. The first decoupling element can be connected to the optical element without the use of an adhesive. For example, the decoupling element can be bonded to the optical element. For example, the first decoupling element can be optically contact bonded to the optical element. For example, the first decoupling element can be securely connected to the base of the respective recess in the optical element. The second decoupling element may be welded, soldered and/or adhesively bonded to the support structure. The second decoupling element may also be screwed to the support structure. The second decoupling element may be adhesively bonded to the first decoupling element.

According to an embodiment, the first decoupling element is arranged within the optical element or on the optical element, at least in sections, wherein the second decoupling element is arranged outside of the optical element, at least in sections.

The first decoupling element can be arranged completely within the optical element. The first decoupling element can be accommodated in the respective recess of the optical element and securely connected to the base of the recess. The second decoupling element projects out of the recess in the direction of the support structure. However, the second decoupling element may be arranged, at least in sections, within the optical element, such as at least in sections within one of the recesses in the optical element.

According to an embodiment, the optical element and the first decoupling element are manufactured from the same substance.

Both the optical element and the decoupling element can be manufactured from ULE. However, other substances may also be used. As a result of the optical element and the first decoupling element being manufactured from the same substance, the optical element and the first decoupling element have the same coefficient of thermal expansion. Hence, mechanical stresses in the optical element and/or in the first decoupling element due to temperature variations are reduced or completely avoided.

According to an embodiment, the first decoupling element and the second decoupling element are manufactured from different substances.

The second decoupling element can be manufactured from a metallic substance. For example, an iron-nickel alloy can be used for the second decoupling element. For example, the second decoupling element can be manufactured from Invar.

According to an embodiment, the first decoupling element comprises a first connection portion, which is connected to the optical element, and a second connection portion, which is connected to the second decoupling element.

The first connection portion can be ring-shaped. However, the first connection portion may also be triangular. The first connection portion is securely connected to the base of one of the recesses in the optical element. The second connection portion is arranged centrally within the first connection portion. The second connection portion is not in contact with the optical element. For example, a gap is provided between the base of the recess and the second connection portion. The second connection portion can move relative to the first connection portion which is secured to the optical element, without the second connection portion coming into contact with the optical element or base of the respective recess. The second connection portion can move along the centre axis of the decoupling device, toward and away from the base of the recess in the optical element. Further, the second connection portion can twist relative to the first connection portion about the centre axis.

According to an embodiment, the first connection portion is connected to the second connection portion with the aid of elastically deformable decoupling arms.

There can be any desired number of decoupling arms. For example, at least two decoupling arms can be provided. However, three, four, five or more than five such decoupling arms may also be provided. For example, the decoupling arms are resiliently deformable. In the present case, the decoupling arms being “elastically deformable” or “resiliently deformable” should be understood to mean that, in particular, the decoupling arms can be brought from a non-deflected or non-deformed state into a deflected or deformed state by the application of a force or a moment. Once the aforementioned force or the moment no longer acts on the decoupling arms, the latter independently or automatically deform back from the deformed state into the non-deformed state. The decoupling device can be stiff when considered along its centre axis. A high axial stiffness of the connection between the optical element and the support structure is relevant for the first eigenmode of the optical system. In this case, “axial” means considered along the centre axis of the decoupling device. However, an axial compensation of deformations arising from a volumetric change in the employed adhesive on account of humidity and/or temperature changes is possible. The decoupling arms can also allow the second connection portion to twist relative to the first connection portion about the centre axis. The decoupling arms do not come into contact with the base of the recess in the optical element. For example, this means that a gap is provided between the decoupling arms and the base. The first decoupling element can be a one-piece component, such as one which is materially in one piece. In the present case, “one piece” or “one part” means that the first connection portion, the second connection portion and the decoupling arms are not composed of different subcomponents, but form a common component. “Materially in one piece” means that the first decoupling element is produced from the same material throughout. For example, the first decoupling element is manufactured from ULE.

According to an embodiment, the decoupling arms run at an angle to the second connection portion starting from the first connection portion.

In particular, “at an angle” should be understood to mean that the decoupling arms do not run perpendicularly to the centre axis of the decoupling device but at an angle thereto. In particular, the decoupling arms run tangentially to the second connection portion. The angled arrangement of the decoupling arms enables a rotational movement of the second connection portion relative to the first connection portion about the centre axis. Further, a radial movement is also possible by way of a bending of the decoupling arms.

According to an embodiment, the second decoupling element comprises at least one flexure.

As mentioned previously, the second decoupling element can be cylindrical. The second decoupling element can comprise a first joining portion, which is connected to the second connection portion, and a second joining portion, which is securely connected to the support structure. A cylindrical base portion is placed between the two joining portions. The first joining portion is connected to the base portion by way of a first flexure. The second joining portion is connected to the base portion by way of a second flexure. The second decoupling element can be a one-piece component, in particular one which is materially in one piece. In the present case, a “flexure” should be understood to mean a region of a component in particular, a region of the second decoupling element in the present case, which, by bending, allows a relative movement between two rigid body regions. In the present case, the first joining portion and the base portion serve as rigid body regions for the first flexure. Accordingly, the second joining portion and the base portion serve as rigid body regions for the second flexure. The second decoupling element ensures the lateral mechanical decoupling.

An optical system for a projection exposure apparatus is also proposed. The optical system comprises an optical assembly, as mentioned above, and an adjustment device operatively connected to the support structure and serving to adjust the optical assembly.

The adjustment device can comprise a plurality of actuating elements or actuators which enable an adjustment or alignment of the optical assembly. The optical assembly has six degrees of freedom, specifically three translational degrees of freedom in each case along a first spatial direction or x-direction, a second spatial direction or y-direction and a third spatial direction or z-direction, and also three rotational degrees of freedom each about the x-direction, the y-direction and the z-direction. That is to say that a position and an orientation of the optical assembly or optically effective surface of the optical element can be determined or described with the aid of the six degrees of freedom.

In particular, the “position” of the optical assembly should be understood to mean its coordinates or the coordinates of a measurement point provided on the optical assembly with respect to the x-direction, the y-direction and the z-direction. In particular, the “orientation” of the optical assembly should be understood to mean its tilt with respect to the three directions. That is to say, the optical assembly can be tilted about the x-direction, the y-direction and/or the z-direction.

This results in the six degrees of freedom for the position and orientation of the optical assembly or optically effective surface of the optical element. A “pose” of the optical assembly comprises both its position and its orientation. The term “pose” is accordingly replaceable by the wording “position and orientation”, and vice versa. In the present case, an “adjustment” or “alignment” should be understood to mean, in particular, a change in the pose of the optical assembly.

When the pose of the optical assembly is changed, the optical element is moved together with the support structure. For example, the optical assembly or the optically effective surface of the optical element can be brought from an actual pose to a target pose, and vice versa, with the aid of the adjustment device. For example, the optical assembly or the optically effective surface in the target pose meets certain desired optical properties, with these not being met by the optical assembly or the optically effective surface in the actual pose.

Furthermore, a projection exposure apparatus having such an optical assembly and/or such an optical system is proposed.

The optical system can be a projection optical unit of the projection exposure apparatus. However, the optical system may also be an illumination system. The projection exposure apparatus can be an EUV lithography apparatus. EUV stands for “extreme ultraviolet” and refers to a wavelength of the working light of between 0.1 nm and 30 nm. The projection exposure apparatus can also be a DUV lithography apparatus. DUV stands for “deep ultraviolet” and refers to a wavelength of the working light of between 30 nm and 250 nm.

“A” or “an” or “one” in the present case should not necessarily be understood to be restrictive to exactly one element. Rather, a plurality of elements, such as two, three or more, can also be provided. Nor should any other numeral used here be understood to the effect that there is a restriction to exactly the stated number of elements. Instead, unless indicated otherwise, numerical deviations upward and downward are possible.

The embodiments and features described for the optical assembly are correspondingly applicable to the proposed optical system and/or to the proposed projection exposure apparatus, and vice versa.

Further possible implementations of the disclosure also encompass not explicitly mentioned combinations of features or embodiments that are described above or hereinafter with respect to the exemplary embodiments. In this case, a person skilled in the art will also add individual aspects as improvements or supplementations to the respective basic form of the disclosure.

Further refinements and aspects of the disclosure are the subject matter of the dependent claims and also of the exemplary embodiments of the disclosure that are described below. The disclosure is explained in greater detail hereinafter on the basis of certain embodiments with reference to the accompanying figures.

### BRIEF DESCRIPTION OF THE DRAWINGS

FIG. 1 shows a schematic meridional section of a projection exposure apparatus for EUV projection lithography;

FIG. 2 shows a schematic view of an embodiment of an optical system for the projection exposure apparatus according to FIG. 1;

FIG. 3 shows a schematic perspective view of an embodiment of an optical assembly for the optical system according to FIG. 2;

FIG. 4 shows a schematic back view of the optical assembly according to FIG. 3;

FIG. 5 shows a schematic front view of the optical assembly according to FIG. 3;

FIG. 6 shows a schematic perspective view of an embodiment of a decoupling device for the optical assembly according to FIG. 3;

FIG. 7 shows a schematic perspective view of an embodiment of a decoupling element for the decoupling device according to FIG. 6;

FIG. 8 shows a schematic back view of the decoupling element according to FIG. 7;

FIG. 9 shows a schematic front view of the decoupling element according to FIG. 7;

FIG. 10 shows a detailed view of the decoupling device according to FIG. 6; and

FIG. 11 shows a further detailed view of the decoupling device according to FIG. 6.

### DETAILED DESCRIPTION

Unless indicated otherwise, elements that are identical or functionally identical have been provided with the same reference signs in the figures. It should also be noted that the illustrations in the figures are not necessarily true to scale.

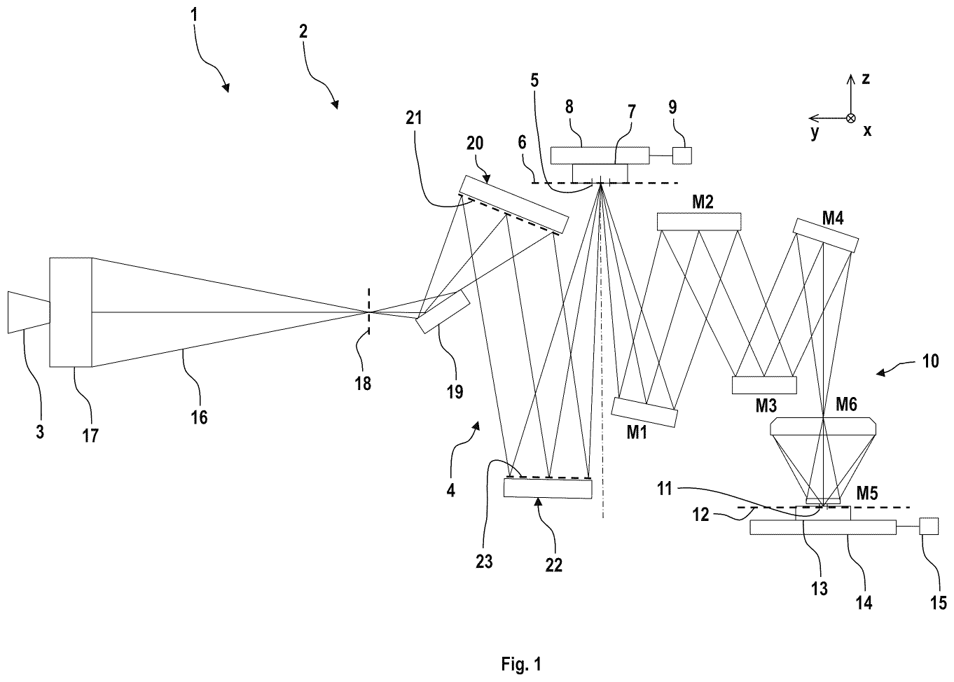

FIG. 1 shows an embodiment of a projection exposure apparatus 1 (lithography apparatus), in particular an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, in particular in a scanning direction.

FIG. 1 shows, for explanatory purposes, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction in FIG. 1 runs in the y-direction y. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, in particular in the y-direction y. The displacement firstly of the reticle 7 by way of the reticle displacement drive 9 and secondly of the wafer 13 by way of the wafer displacement drive 15 can be implemented so as to be mutually synchronized.

The light source 3 is an EUV radiation source. The light source 3 emits in particular EUV radiation 16, which is also referred to below as used radiation, illumination radiation or illumination light. In particular, the used radiation 16 has a wavelength in the range between 0.1 nm and 30 nm. The light source 3 may be a plasma source, for example an LPP (short for: laser produced plasma) source or a DPP (short for: gas-discharge produced plasma) source. It may also be a synchrotron-based radiation source. The light source 3 may be an FEL (short for: free-electron laser).

The illumination radiation 16 emanating from the light source 3 is focused by a collector 17. The collector 17 can be a collector with one or more ellipsoidal and/or hyperboloidal reflection surfaces. The at least one reflection surface of the collector 17 may be impinged upon by the illumination radiation 16 with grazing incidence (abbreviated as: GI), which is to say with angles of incidence greater than 45°, or with normal incidence (abbreviated as: NI), which is to say with angles of incidence less than 45°. The collector 17 may be structured and/or coated, both to optimize its reflectivity for the used radiation and to suppress extraneous light.

Downstream of the collector 17, the illumination radiation 16 propagates through an intermediate focus in an intermediate focal plane 18. The intermediate focal plane 18 may represent a separation between a radiation source module, having the light source 3 and the collector 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect that goes beyond the purely deflecting effect. In an alternative or in addition, the deflection mirror 19 may be in the form of a spectral filter that separates a used light wavelength of the illumination radiation 16 from extraneous light at a wavelength deviating therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which may also be referred to as field facets. Only some of these first facets 21 are shown in FIG. 1 by way of example.

The first facets 21 may be embodied as macroscopic facets, in particular as rectangular facets or as facets with an arcuate or part-circular edge contour. The first facets 21 may be in the form of plane facets or alternatively in the form of convexly or concavely curved facets.

As is known for example from DE 10 2008 009 600 A1, the first facets 21 themselves may also each be composed of a multiplicity of individual mirrors, in particular a multiplicity of micromirrors. The first facet mirror 20 may in particular be in the form of a microelectromechanical system (MEMS system). For details, reference is made to DE 10 2008 009 600 A1.

Between the collector 17 and the deflection mirror 19, the illumination radiation 16 propagates horizontally, i.e. in the y-direction y.

In the beam path of the illumination optical unit 4, a second facet mirror 22 is arranged downstream of the first facet mirror 20. Provided the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can, for example, have a round, rectangular or hexagonal boundary, or alternatively be facets composed of micromirrors. In this regard, reference is likewise made to DE 10 2008 009 600 A1.

The second facets 23 can have plane or, alternatively, convexly or concavely curved reflection surfaces.

The illumination optical unit 4 thus forms a double-faceted system. This fundamental principle is also referred to as a fly's eye condenser (or integrator).

It may be advantageous to arrange the second facet mirror 22 not exactly within a plane that is optically conjugate to a pupil plane of the projection optical unit 10. In particular, the second facet mirror 22 may be arranged so as to be tilted in relation to a pupil plane of the projection optical unit 10, as is described for example in DE 10 2017 220 586 A1.

With the aid of the second facet mirror 22, the individual first facets 21 are imaged into the object field 5. The second facet mirror 22 is the last beam-shaping mirror or indeed the last mirror for the illumination radiation 16 in the beam path upstream of the object field 5.

In a further embodiment (not illustrated) of the illumination optical unit 4, a transfer optical unit may be arranged in the beam path between the second facet mirror 22 and the object field 5, and contributes in particular to the imaging of the first facets 21 into the object field 5. The transfer optical unit may have exactly one mirror or, alternatively, two or more mirrors, which are arranged in succession in the beam path of the illumination optical unit 4. The transfer optical unit may in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In a further embodiment of the illumination optical unit 4, there is also no need for the deflection mirror 19, and so the illumination optical unit 4 may then have exactly two mirrors downstream of the collector 17, specifically the first facet mirror 20 and the second facet mirror 22.

The imaging of the first facets 21 into the object plane 6 using the second facets 23 or using the second facets 23 and a transfer optical unit is, as a rule, only approximate imaging.

The projection optical unit 10 comprises a plurality of mirrors Mi, which are consecutively numbered in accordance with their arrangement in the beam path of the projection exposure apparatus 1.

In the example shown in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a through opening for the illumination radiation 16. The projection optical unit 10 has an image-side numerical aperture that is greater than 0.5 and may also be greater than 0.6 and may be for example 0.7 or 0.75.

Reflection surfaces of the mirrors Mi may be designed as freeform surfaces without an axis of rotational symmetry. Alternatively, the reflection surfaces of the mirrors Mi may be designed as aspherical surfaces with exactly one axis of rotational symmetry of the reflection surface shape. Just like the mirrors of the illumination optical unit 4, the mirrors Mi may have highly reflective coatings for the illumination radiation 16. These coatings may be designed as multilayer coatings, in particular with alternating layers of molybdenum and silicon.

The projection optical unit 10 has a large object-image offset in the y-direction y between a y-coordinate of a centre of the object field 5 and a y-coordinate of the centre of the image field 11. This object-image offset in the y-direction y may be of approximately the same magnitude as a z-distance between the object plane 6 and the image plane 12.

The projection optical unit 10 may in particular have an anamorphic form. It has in particular different imaging scales βx, βy in the x- and y-directions x, y. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, which is to say in a direction perpendicular to the scanning direction.

The projection optical unit 10 leads to a reduction in size of 8:1 in the y-direction y, which is to say in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 may be the same or may differ, depending on the embodiment of the projection optical unit 10. Examples of projection optical units with different numbers of such intermediate images in the x- and y-directions x, y are known from US 2018/0074303 A1.

In each case one of the second facets 23 is assigned to exactly one of the first facets 21 for respectively forming an illumination channel for illuminating the object field 5. This may in particular result in illumination according to the Köhler principle. The far field is decomposed into a multiplicity of object fields 5 with the aid of the first facets 21. The first facets 21 produce a plurality of images of the intermediate focus on the second facets 23 respectively assigned to them.

By way of an assigned second facet 23, the first facets 21 are in each case imaged onto the reticle 7 in a manner overlaid on one another for the purposes of illuminating the object field 5. The illumination of the object field 5 is in particular as homogeneous as possible. It can have a uniformity error of less than 2%. Field uniformity can be achieved by superposing different illumination channels.

The illumination of the entrance pupil of the projection optical unit 10 may be defined geometrically by an arrangement of the second facets 23. The intensity distribution in the entrance pupil of the projection optical unit 10 may be set by selecting the illumination channels, in particular the subset of the second facets 23, which guide light. This intensity distribution is also referred to as illumination setting or illumination pupil filling.

A likewise preferred pupil uniformity in the region of portions of an illumination pupil of the illumination optical unit 4 which are illuminated in a defined manner may be achieved by a redistribution of the illumination channels.

Further aspects and details of the illumination of the object field 5 and in particular of the entrance pupil of the projection optical unit 10 are described below.

In particular, the projection optical unit 10 can comprise a homocentric entrance pupil. The latter may be accessible. It may also be inaccessible.

The entrance pupil of the projection optical unit 10 regularly cannot be exactly illuminated with the second facet mirror 22. When imaging the projection optical unit 10, which images the centre of the second facet mirror 22 telecentrically onto the wafer 13, the aperture rays often do not intersect at a single point. However, it is possible to find an area in which the spacing of the aperture rays that is determined in pairs becomes minimal. This area represents the entrance pupil or an area in real space that is conjugate thereto. In particular, this area has a finite curvature.

It may be the case that the projection optical unit 10 has different poses of the entrance pupil for the tangential beam path and for the sagittal beam path. In this case, an imaging element, in particular an optical component of the transfer optical unit, should be provided between the second facet mirror 22 and the reticle 7. With the aid of this optical element, the different poses of the tangential entrance pupil and the sagittal entrance pupil can be taken into account.

In the arrangement of the component parts of the illumination optical unit 4 shown in FIG. 1, the second facet mirror 22 is arranged in an area conjugate to the entrance pupil of the projection optical unit 10. The first facet mirror 20 is arranged tilted in relation to the object plane 6. The first facet mirror 20 is arranged tilted in relation to an arrangement plane defined by the deflection mirror 19. The first facet mirror 20 is arranged tilted in relation to an arrangement plane defined by the second facet mirror 22.

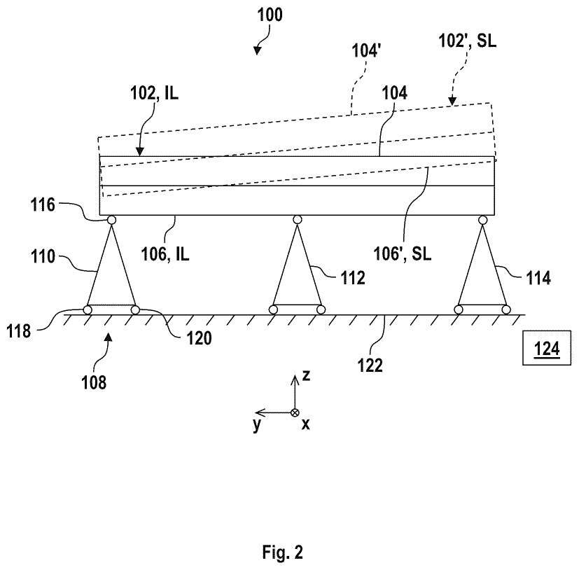

FIG. 2 shows a schematic view of an embodiment of an optical system 100 for the projection exposure apparatus 1.

The optical system 100 can be part of a projection optical unit 10 as explained above. However, the optical system 100 can also be part of an illumination optical unit as mentioned above. However, it is assumed below that the optical system 100 is part of a projection optical unit 10 of this type. The optical system 100 is suitable for EUV lithography. However, the optical system 100 can also be suitable for DUV lithography.

The optical system 100 comprises an optical assembly 102. The optical assembly 102 can be a mirror or comprise a mirror. For example, the optical assembly 102 is one of the mirrors M1 to M6. The optical assembly 102 may also be referred to as mirror module. The optical assembly 102 comprises an optical element 104. The optical element 104 may be a mirror.

In addition to the optical element 104, the optical assembly 102 comprises a support structure 106 which carries the optical element 104. The optical element 104 is coupled to the support structure 106. The type of coupling between the optical element 104 and the support structure 106 will still be explained hereinbelow.

The optical element 104 is manufactured from glass, glass ceramics or the like. In particular, the optical element 104 can be manufactured from Ultra Low Expansion Glass (ULE). The support structure 106 is manufactured from a material which differs from the material used to manufacture the optical element 104. In particular, the material of the support structure 106 has a higher Young's modulus than the material of the optical element 104. The support structure 106 can be manufactured from a more cost-effective material than the optical element 104. As a result, the optical assembly 102 can be produced cost effectively.

The support structure 106 has a greater stiffness than the optical element 104. In this case, the “stiffness” should be understood to mean, in particular, the resistance of a body to an elastic deformation applied by an external load. The stiffness provides the correlation between the load on the body and its deformation. The stiffness is determined by the substance of the body and its geometry.

For example, in the case of two geometrically identical bodies, the body whose material used to manufacture the respective body has the higher Young's modulus has the greater stiffness. Hence, the different stiffnesses of the optical element 104 and support structure 106 can be obtained by different geometries and/or by the use of different materials or substances.

The optical assembly 102 or the optical element 104 has six degrees of freedom, specifically three translational degrees of freedom in each case along the first spatial direction or x-direction x, the second spatial direction or y-direction y, and the third spatial direction or z-direction z, and also three rotational degrees of freedom each about the x-direction x, the y-direction y, and the z-direction z. That is to say that a position and an orientation of the optical assembly 102 or optical element 104 can be determined or described with the aid of the six degrees of freedom.

The “position” of the optical assembly 102 or optical element 104 is in particular understood to mean the coordinates thereof or the coordinates of a measurement point provided on the optical assembly 102 with respect to the x-direction x, the y-direction y, and the z-direction z.

The “orientation” of the optical assembly 102 or optical element 104 is understood to mean in particular the tilt thereof with respect to the three directions x, y, z. That is to say that the optical assembly 102 or the optical element 104 can be tilted about the x-direction x, the y-direction y, and/or the z-direction z.

This results in the six degrees of freedom for the position and orientation of the optical assembly 102 or optical element 104. A “pose” of the optical assembly 102 or optical element 104 comprises both its position and its orientation. The term “pose” is accordingly replaceable by the wording “position and orientation”, and vice versa.

FIG. 2 shows an actual pose IL of the optical assembly 102 or optical element 104 using solid lines and a target pose SL of the optical assembly 102 or optical element 104 using dashed lines and the reference signs 102′ and 104′. An actual pose IL of the support structure 106 coupled to the optical element 104 is also depicted using solid lines. A target pose SL of the support structure 106 is depicted using dashed lines and the reference sign 106′.

The optical assembly 102 can be brought from its actual pose IL to the target pose SL and vice versa. For example, the optical assembly 102 or the optical element 104 in the target pose SL meets certain desired optical properties, with these not being met by the optical assembly 102 or the optical element 104 in the actual pose IL.

In order to move the optical assembly 102 from the actual pose IL to the target pose SL, the optical system 100 comprises an adjustment device 108. The adjustment device 108 is configured for adjusting the optical assembly 102. In the present case, an “adjustment” or “alignment” should be understood to mean, in particular, a change in the pose of the optical assembly 102. When the pose of the optical assembly 102 is changed, the optical element 104 is moved together with the support structure 106.

For example, the optical assembly 102 can be brought from the actual pose IL to the target pose SL and vice versa with the aid of the adjustment device 108. The adjustment or alignment of the optical assembly 102 can thus be carried out with the aid of the adjustment device 108 in all six aforementioned degrees of freedom. The adjustment device 108 is what is known as a hexapod or can be referred to as such.

The adjustment device 108 comprises a plurality of actuators 110, 112, 114, which are shown only very schematically in FIG. 2. The actuators 110, 112, 114 can also be referred to as actuator systems or actuating elements. The actuators 110, 112, 114 can be what are known as bipods or can be referred to as such. Provision can be made of exactly three actuators 110, 112, 114, which are arranged offset by 120° from one another. The actuators 110, 112, 114 can have identical designs.

The actuators 110, 112, 114 are joined to the support structure 106 with the aid of joining points 116, only one of which has been provided with a reference sign in FIG. 2. For example, an adhesive connection or a screwed connection may be provided at each of the joining points 116. For example, exactly three joining points 116 may be provided, with each joining point 116 being assigned an actuator 110, 112, 114.

Further, each actuator 110, 112, 114 is coupled to a fixed world 122 via two joining points 118, 120, only two of which have been provided with a reference sign in FIG. 2. The fixed world 122 can be a force frame or any other immovable structure.

With the aid of the actuators 110, 112, 114, the optical assembly 102 is able to be moved vis-à-vis the fixed world 122. Each actuator 110, 112, 114 may be assigned two of the aforementioned degrees of freedom. Using the three actuators 110, 112, 114, an adjustment of the optical assembly 102 in all six degrees of freedom is thus possible.

The actuators 110, 112, 114 are controllable with the aid of an open-loop and closed-loop control unit 124 of the adjustment device 108, in order to adjust the optical assembly 102. All actuators 110, 112, 114 are operatively connected to the open-loop and closed-loop control unit 124, and as a result the open-loop and closed-loop control unit 124 can adjust the optical assembly 102 in all six degrees of freedom with the aid of a suitable control of these actuators 110, 112, 114. This can be implemented on the basis of sensor signals from a sensor system (not depicted here), which is able to detect the actual pose IL and the target pose SL of the optical assembly 102.

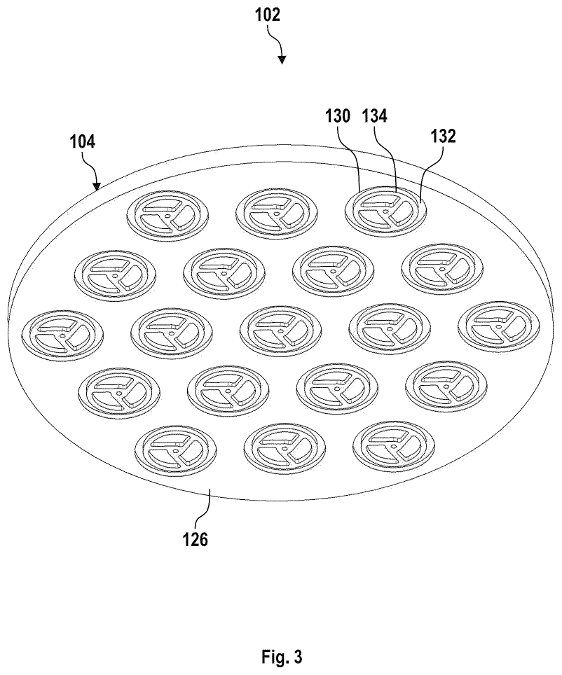

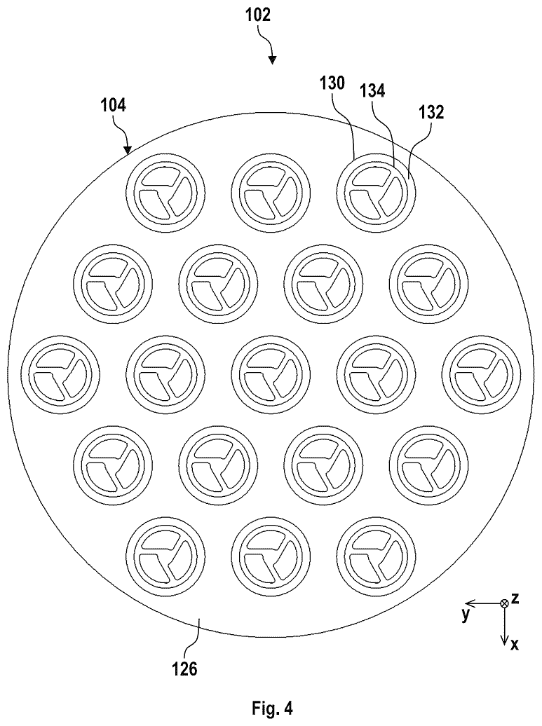

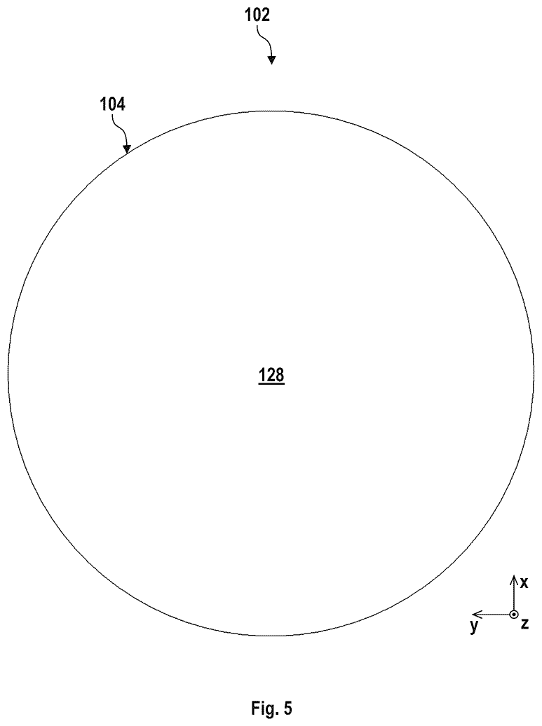

FIG. 3 shows a schematic perspective view of the optical assembly 102. FIG. 4 shows a schematic back view of the optical assembly 102. FIG. 5 shows a schematic plan view of the optical assembly 102. In the following reference is made to FIGS. 3 to 5 simultaneously.

The support structure 106 has not been shown in FIGS. 3 to 5. The optical element 104 comprises a back side 126 facing the support structure 106 and an optically effective surface 128 facing away from the back side 126. The optically effective surface 128 is a mirror surface. The optically effective surface 128 is suitable for reflecting illumination radiation 16. The optically effective surface 128 can be realized by a coating.

A multiplicity of depressions or recesses 130, only one of which has been provided with a reference sign in FIGS. 3 and 4, are provided on the back side 126. There can be any desired number of recesses 130. For example, 19 recesses 130 may be provided. The recesses 130 can be arranged in grid-like or pattern-like fashion. In the present case, “grid-like” or “pattern-like” means that, in particular, the recesses 130 may be arranged in rows and columns. The recesses 130 may be placed offset from one another.

The recesses 130 can be circular. However, in principle, the recesses 130 may have any desired geometry. For example, the recesses 130 are oval, rectangular or hexagonal. Each recess 130 comprises a base 132. The base 132 is set back in relation to the back side 126 of the optical element 104.

A decoupling device 134 is accommodated in each recess 130. That is to say, the number of decoupling devices 134 corresponds to the number of recesses 130. The decoupling devices 134 are coupled to the bases 132 of the recesses 130. Only one decoupling device 134 is discussed in more detail hereinafter.

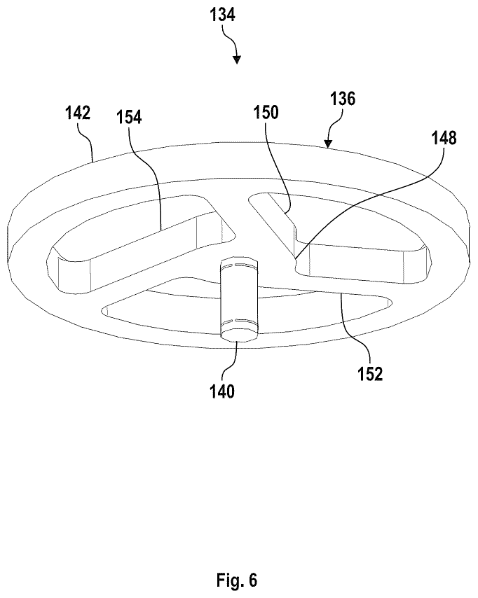

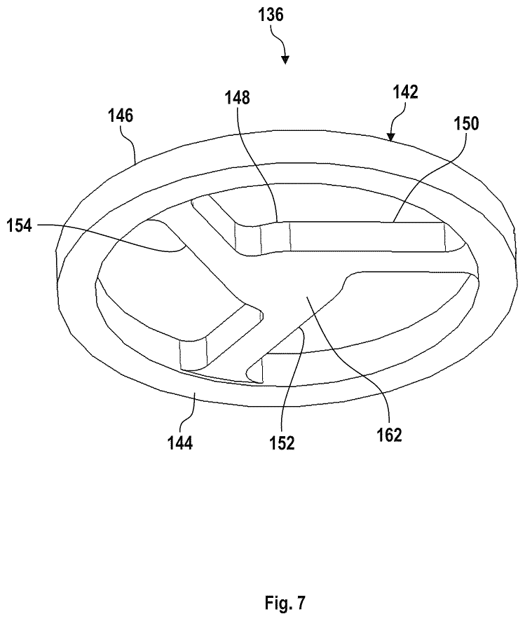

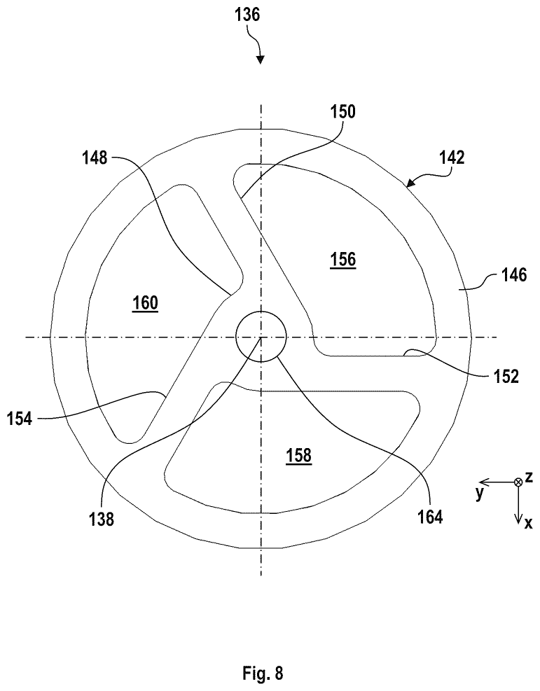

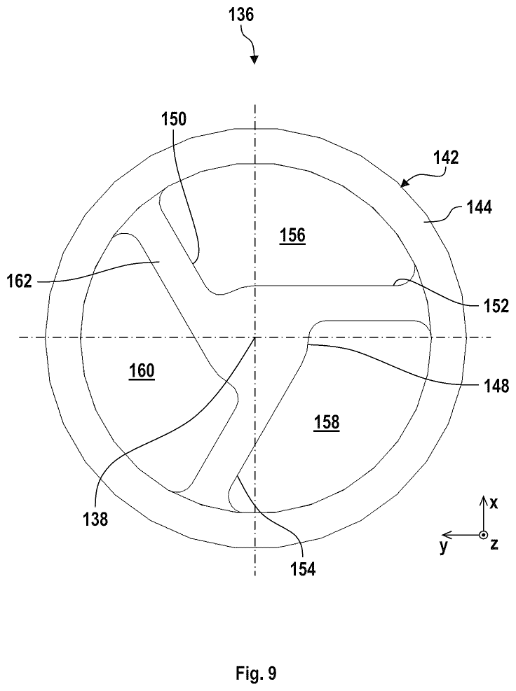

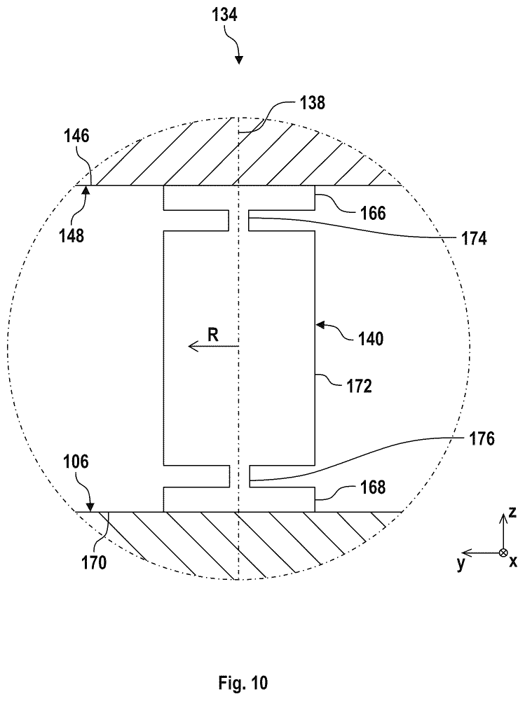

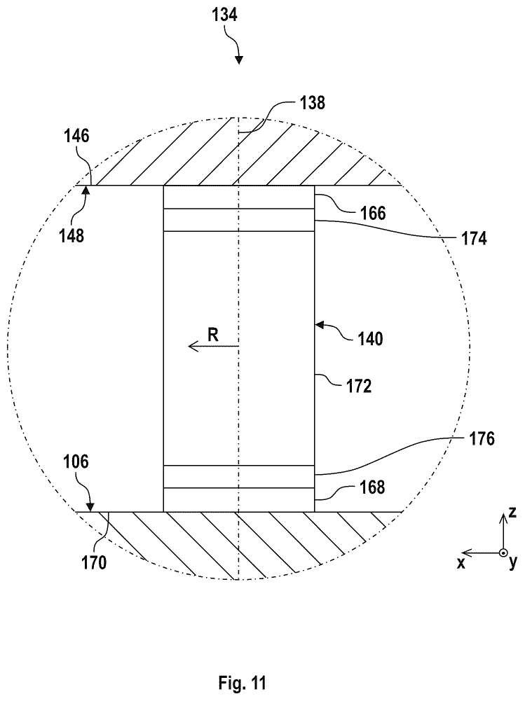

FIG. 6 shows a schematic perspective view of an embodiment of a decoupling element 134 as mentioned previously. FIG. 7 shows a schematic perspective view of an embodiment of a first decoupling element 136 for the decoupling device 134. FIG. 8 shows a schematic back view of the first decoupling element 136. FIG. 9 shows a schematic front view of the first decoupling element 136. FIG. 10 shows a schematic detailed view of the decoupling device 134. FIG. 11 shows a further schematic detailed view of the decoupling device 134. In the following reference is made to FIGS. 6 to 11 simultaneously.

The coupling device 134 can be assigned an axis of symmetry or centre axis 138, in relation to which the decoupling device 134 has a substantially rotationally symmetric structure. The decoupling device 134 is also assigned a radial direction R. The radial direction R is oriented perpendicularly to the centre axis 138 and away from the latter.

The decoupling device 134 comprises the optionally ring-shaped first decoupling element 136 and a rod-shaped second decoupling element 140. The decoupling elements 136, 140 are connected to one another. The first decoupling element 136 is connected to the optical element 104. The second decoupling element 140 is coupled to the support structure 106. Thus, the optical element 104 and the support structure 106 are operatively connected to one another with the aid of the decoupling device 134.

The first decoupling element 136 is manufactured from the same substance as the optical element 104. For example, the first decoupling element 136 can be manufactured from ULE. The second decoupling element 140 is manufactured from a material which differs from the material used to manufacture the first decoupling element 136. For example, the second decoupling element 140 is manufactured from a metallic substance, for example an iron-nickel alloy, in particular Invar.

The first decoupling element 136 comprises a ring-shaped first connection portion 142. In principle, however, the first connection portion 142 may have any desired geometry. For example, the first connection portion 142 may be triangular or rectangular.

The first connection portion 142 has a front side 144 facing the base 132 of the respective recess 130 and a back side 146 facing away from the front side 144. The front-side 144 is ring-shaped. The first connection portion 142 is connected to the base 132 with the aid of the front side 144. An adhesive-free bonding method is used to this end. Hence, the front side 144 and the base 132 are bonded to one another.

For example, optical contact bonding is used to connect the front side 144 of the first decoupling element 136 to the base 132. Further, a welded connection may also be provided between the first decoupling element 136 and the optical element 104. The first decoupling element 136 may also be formed in one piece, in particular materially in one piece, with the optical element 104. In the present case, “one piece” or “one part” means that, in particular, the first decoupling element 136 and the optical element 104 are not composed of different subcomponents, but form a common component. In particular, “materially in one piece” means that the first decoupling element 136 and the optical element 104 are manufactured from the same material, for example ULE, throughout.

A second connection portion 148 is arranged within the first connection portion 142. The second connection portion 148 is placed centrally within the first connection portion 142. The first connection portion 142 and the second connection portion 148 are connected to one another with the aid of decoupling arms 150, 152, 154.

There can be any desired number of decoupling arms 150, 152, 154. For example, exactly three decoupling arms 150, 152, 154 are provided. Openings 156, 158, 160 are provided between the decoupling arms 150, 152, 154. The decoupling arms 150, 152, 154 do not extend centrically toward the centre axis 138 but are arranged at an angle to the latter. This allows the second connection portion 148 to twist relative to the first connection portion 142. The decoupling arms 150, 152, 154 are deformed in the process.

The decoupling arms 150, 152, 154 are elastically deformable, in particular resiliently deformable. In particular, this means that the decoupling arms 150, 152, 154 can be brought from a non-deflected or non-deformed state into a deflected or deformed state by the application of a force or moment. Once this force or this moment no longer acts, the decoupling arms 150, 152, 154 independently or automatically deform back from the deformed state to the non-deformed state.

The first decoupling element 136 is a one-piece component, in particular one which is materially in one piece. In the present case, “one piece” or “one part” means that, in particular, the two connection portions 142, 148 and the decoupling arms 150, 152, 154 are not composed of different subcomponents, but form a common component, specifically the first decoupling element 136. In particular, “materially in one piece” means that the first decoupling element 136 is manufactured from the same material, for example ULE, throughout.

The second connection portion 148 and the decoupling arms 150, 152, 154 form a common front side 162. The front side 162 is set back in relation to the front side 144 connected to the base 132, with the result that a gap is provided between the front side 162 and the base 132. In particular, this means that the decoupling arms 150, 152, 154 do not come into contact with the base 132. Consequently, the decoupling arms 150, 152, 154 are freely deformable without these colliding with the base 132.

Facing away from the front side 162, the first connection portion 142, the second connection portion 148 and the decoupling arms 150, 152, 154 form the common back side 146. On the back side 146, a joining region 164 is provided centrally on the second connection portion 148. The second connection portion 148 is connected to the second decoupling element 140, for example by way of an adhesive bond, with the aid of the joining region 164. The joining region 164 can be an adhesive bonding spot.

The second decoupling element 140—as shown in FIGS. 10 and 11—is constructed substantially rotationally symmetrically with respect to the centre axis 138. The second coupling element 140 has a disc-shaped first joining portion 166 which is connected on the back side 146 to the second connection portion 148, in particular by way of adhesive bonding. The first joining portion 166 is adhesively bonded to the joining region 164.

In addition to the first joining portion 166, the second decoupling element 140 comprises a disc-shaped second joining portion 168, which is securely connected to the support structure 106, in particular to a front side 170 of the support structure 106 facing the optical element 104. An adhesive connection may be provided. The second joining portion 168 may also be soldered or welded to the front side 170.

A cylindrical base portion 172 is placed between the two joining portions 166, 168. The first joining portion 166 is connected to the base portion 172 by way of a first flexure 174. The second joining portion 168 is connected to the base portion 172 by way of a second flexure 176.

The second decoupling element 140 is a one-piece component, in particular one which is materially in one piece. In particular, this means that the joining portions 166, 168 and the base portion 172 form a common component, specifically the second decoupling element 140. In the process, the second decoupling element 140 may be manufactured from the same substance throughout.

In the present case, a “flexure” should be understood to mean a region of a component, a region of the second decoupling element 140 in the present case, which, by bending, allows a relative movement between two rigid body regions. In the present case, the first joining portion 166 and the base portion 172 serve as rigid body regions for the first flexure 174. Accordingly, the second joining portion 168 and the base portion 172 serve as rigid body regions for the second flexure 176.

Both radial and lateral decoupling is possible with the aid of the decoupling device 134. “Axial” means along the centre axis 138. In this case, “radial” means along and counter to the radial direction R or perpendicular to the centre axis 138. The radial decoupling is implemented with the aid of the second decoupling element 140 or with the aid of the flexures 174, 176.

The axial decoupling is realized by the elastically deformable decoupling arms 150, 152, 154. The decoupling arms 150, 152, 154 allow both a twist of the second connection portion 148 relative to the first connection portion 142 and a movement of the second connection portion 148 along the centre axis 138, toward and away from the base 132. As a result of the first decoupling element 136 being recessed in one of the recesses 130, decoupling is rendered possible immediately below the optically effective surface 128 of the optical element 104.

The joining region 164, where the adhesive is provided for interconnecting the first decoupling element 136 and the second decoupling element 140, is mechanically decoupled from the optical element 104 with the aid of the decoupling arms 150, 152, 154. Hence, parasitic forces arising from curing, cross-linking or ageing of the adhesive and from a moisture- and/or temperature-related change in its volume cannot be transferred to the optical element 104. This reliably prevents an unwanted deformation of the optically effective surface 128.

The optical assembly 102 can comprise at least three decoupling devices 134. However, four, five or more than five such decoupling devices 134 may also be provided. The stiffness of the optical assembly 102 increases with increase in the number of decoupling devices 134, and a higher frequency of the optical assembly 102 can be attained. The first decoupling element 136 adopts axial decoupling along the centre axis 138. Lateral decoupling is implemented by the flexures 174, 176 of the second decoupling element 140.

Although the present disclosure has been described on the basis of exemplary embodiments, it can be modified in diverse ways.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Optical system
102 Optical assembly
102′ Optical assembly
104 Optical element
104′ Optical element
106 Support structure
106′ Support structure
108 Adjustment device
110 Actuator
112 Actuator
114 Actuator
116 Joining point
118 Joining point
120 Joining point
122 Fixed world
124 Open-loop and closed-loop control unit
126 Back side
128 Optically effective surface
130 Recess
132 Base
134 Decoupling device
136 Decoupling element
138 Centre axis
140 Decoupling element
142 Connection portion
144 Front side
146 Back side
148 Connection portion
150 Decoupling arm
152 Decoupling arm
154 Decoupling arm
156 Opening
158 Opening
160 Opening
162 Front side
164 Joining region
166 Joining portion
168 Joining portion
170 Front side
172 Base portion
174 Flexure
176 Flexure
IL Actual pose
M1 Mirror
M2 Mirror
M3 Mirror
M4 Mirror
M5 Mirror
M6 Mirror
R Radial direction
SL Target pose
x x-direction
y y-direction
Z z-direction

What is claimed is:

1. An optical assembly, comprising:
an optical element;
a support structure carrying the optical element; and
a plurality of decoupling devices between the optical element and the support structure,
wherein:
the plurality of decoupling devices are configured to mechanically decouple the optical element from the support structure;
each decoupling device comprises a first decoupling element and a second decoupling element connected to the first decoupling element;
the first decoupling element is connected to the optical element without an adhesive; and
the second decoupling is connected to the support structure.

2. The optical assembly of claim 1, wherein at least sections of the decoupling devices are arranged within the optical element or on the optical element.

3. The optical assembly of claim 2, wherein the decoupling devices are configured to mechanically decouple the optical element both axially and laterally from the support structure.

4. The optical assembly of claim 1, wherein the decoupling devices are configured to mechanically decouple the optical element both axially and laterally from the support structure.

5. The optical assembly of claim 1, wherein the support structure has a greater stiffness than the optical element.

6. The optical assembly of claim 5, wherein at least sections of the decoupling devices are arranged within the optical element or on the optical element.

7. The optical assembly of claim 1, wherein the support structure comprises a first substance, the optical element comprises a second substance, and the first substance has a higher Young's modulus than the second substance.

8. The optical assembly of claim 7, wherein at least sections of the decoupling devices are arranged within the optical element or on the optical element.

9. The optical assembly of claim 1, wherein:
at least sections of the first decoupling element are within the optical element or on the optical element; and
at least sections of the second decoupling element are outside the optical element.

10. The optical assembly of claim 9, wherein at least sections of the decoupling devices are arranged within the optical element or on the optical element.

11. The optical assembly of claim 1, wherein the optical element and the first decoupling element comprise the same substance.

12. The optical assembly of claim 1, wherein the first decoupling element comprises a first substance, and the second decoupling element comprises a second substance different from the first substance.

13. The optical assembly of claim 1, wherein the first decoupling element comprises a first connection portion connected to the optical element, and the first decoupling element comprises a second connection portion connected to the second decoupling element.

14. The optical assembly of claim 13, further comprising elastically deformable arms connecting the first connection portion to the second connection portion.

15. The optical assembly of claim 14, wherein the decoupling arms run at an angle to the second connection portion starting from the first connection portion.

16. The optical assembly of claim 1, wherein the second decoupling element comprises a flexure.

17. An optical system, comprising:
an optical assembly according to claim 1; and
an adjustment device configured to adjust the optical assembly.

18. An apparatus, comprising:
an optical assembly according to claim 1,
wherein the apparatus is a projection exposure apparatus.

19. The apparatus of claim 18, further comprising an adjustment device configured to adjust the optical assembly.

20. The apparatus of claim 18, wherein the apparatus is an EUV projection exposure apparatus.
